(19) United States
(12) Patent Application Publication
(10) Pub. No.: US 2025/0080056 A1
(43) Pub. Date: Mar. 6, 2025

(54) SEMICONDUCTOR DEVICE AND POWER AMPLIFICATION MODULE

(71) Applicant: Murata Manufacturing Co., Ltd., Kyoto (JP)

(72) Inventors: Masatoshi KAMITANI, Kyoto (JP); Fumio HARIMA, Kyoto (JP); Yoshiaki SUKEMORI, Kyoto (JP); Yuuki NAKANO, Kyoto (JP)

(21) Appl. No.: 18/823,893

(22) Filed: Sep. 4, 2024

(30) Foreign Application Priority Data
Sep. 5, 2023 (JP) 2023-143876

(51) Int. Cl. H03F 1/30

(52) U.S. Cl. CPC H03F 1/30; H03F 2200/21; H03F 2200/447; H03F 2200/468

(57) ABSTRACT

A semiconductor device includes: a first semiconductor element in which a plurality of transistors arranged in one direction are electrically connected in parallel, and a second semiconductor element provided in both end portions in the arrangement direction of the transistors, wherein the lower an ambient temperature is, the greater a current flowing through the second semiconductor element relatively increases.

### CROSS REFERENCE TO RELATED APPLICATION

This application claims priority from Japanese Patent Application No. 2023-143876 filed on Sep. 5, 2023. The content of this application is incorporated herein by reference in its entirety.

### BACKGROUND ART

The present disclosure relates to a semiconductor device and a power amplification module.

As a technology for increasing the efficiency of a power amplification circuit mounted on a radio communication terminal, there is known a semiconductor device in which a power amplifier is configured by electrically connecting a plurality of transistors in parallel on one single chip (see, for example, Japanese Patent No. 2580966). Also, there is known a multi-finger type heterojunction bipolar transistor in which high output and miniaturization are both achieved by connecting a plurality of heterojunction bipolar transistors (HBTs), which can perform high efficiency operation, in parallel in a row in the short side direction of the emitter fingers (see, for example, Japanese Unexamined Patent Application Publication No. 2007-027269). Japanese Unexamined Patent Application Publication No. 2007-027269 discloses a structure in which non-uniformity of heat generated in the HBT cells is taken into account. Specifically, since the emitter fingers in the central portion are affected by the heat from the emitter fingers in the peripheral portions, the temperature of the emitter fingers in the central portion become higher.

### BRIEF SUMMARY

In recent years, there has been a desire for a power amplification device that can be used even in extremely cold regions, such as those below-30 degrees Centigrade. A bipolar transistor such as an HBT generally has a lower breakdown voltage under a low temperature environment. Thus, there is a possibility that, under a cryogenic environment below-30 degrees Centigrade, for example, overvoltage may occur at junctions located in the end portions of the device.

The present disclosure provides a semiconductor device and a power amplification module capable of expanding the lower limit of an operating temperature range.

A semiconductor device according to an aspect of the present disclosure includes: a first semiconductor element in which a plurality of transistors arranged in one direction are electrically connected in parallel; and a second semiconductor element provided in both end portions in the arrangement direction of the transistors, wherein the lower an ambient temperature is, the greater a current flowing through the second semiconductor element relatively increases.

In such a configuration, the lower the ambient temperature is, the more the heating value of the second semiconductor element increases, and therefore the more the junction temperature at the position corresponding to the junction of the second semiconductor element rises. Accordingly, the closer to the junction of the second semiconductor element, the more the junction temperature rises at the position corresponding to each junction of the first semiconductor element.

A power amplification module according to an aspect of the present disclosure includes: the semiconductor device described above; a substrate on which the semiconductor device is flip-chip mounted; and a bump provided between the semiconductor device and the substrate, wherein, in plan view, the bump is provided in a region overlapping the first semiconductor element and is not provided in a region overlapping the second semiconductor element.

In such a configuration, the heat dissipation from the position corresponding to the junction of the second semiconductor element is suppressed. As a result, the junction temperature at the position corresponding to the junction of the second semiconductor element can be increased.

A power amplification module according to an aspect of the present disclosure includes: the semiconductor device described above; and a substrate on which the semiconductor device is wire-bonded, wherein, in plan view, the semiconductor device is provided with a heat dissipating via in a region overlapping the first semiconductor element and is not provided with the heat dissipating via in a region overlapping the second semiconductor element.

In such a configuration, the heat dissipation from the position corresponding to the junction of the second semiconductor element is suppressed. As a result, the junction temperature at the position corresponding to the junction of the second semiconductor element can be increased.

According to the present disclosure, it is possible to realize a semiconductor device and a power amplification module capable of expanding the lower limit of the operating temperature range.

### BRIEF DESCRIPTION OF THE DRAWINGS

FIG. 1 is a schematic diagram showing an example of a power amplification module;

FIG. 2 is a transparent top view of a semiconductor device;

FIG. 3 is a diagram showing an example of an internal circuit configuration of the semiconductor device;

FIG. 4 is a schematic graph showing an example of temperature characteristics of a bias current supplied to a semiconductor element;

FIG. 5 is a schematic graph showing junction temperatures of the semiconductor device under a cryogenic environment;

FIG. 6 is a transparent top view of a semiconductor device according to Embodiment 1;

FIG. 7 is a diagram showing an example of an internal circuit configuration of the semiconductor device according to Embodiment 1;

FIG. 8 is a schematic graph showing an example of temperature characteristics of bias currents supplied to a second semiconductor element;

FIG. 9 is a diagram showing an example of the change in junction temperature of the semiconductor device according to Embodiment 1 with respect to the change in ambient temperature;

FIG. 10 is a schematic graph showing junction temperature of the semiconductor device according to Embodiment 1 under a cryogenic environment;

FIG. 11 is a diagram showing an example of an internal circuit configuration of a semiconductor device according to Embodiment 2;

FIG. 12A is a diagram showing an example of an internal circuit configuration of a semiconductor device according to Embodiment 3;

FIG. 12B is a diagram showing an example of an internal circuit configuration of the semiconductor device according to Embodiment 3;

FIG. 13 is a cross-sectional view taken along the X direction of a power amplification module according to Embodiment 4; and

FIG. 14 is a cross-sectional view taken along the X direction of a power amplification module according to Embodiment 5.

### DETAILED DESCRIPTION

A semiconductor device and a power amplification module according to each embodiment will be described in detail below with reference to the drawings. The present disclosure is not limited by the embodiment. Each embodiment is an example; and it is needless to say that partial replacement or combination of the configurations shown in the different embodiments is possible. In Embodiment 2 and subsequent embodiments, the description of matters common to Embodiment 1 will be omitted, and only different points will be described. In particular, similar effects by similar configurations will not be referred to one by one in each embodiment.

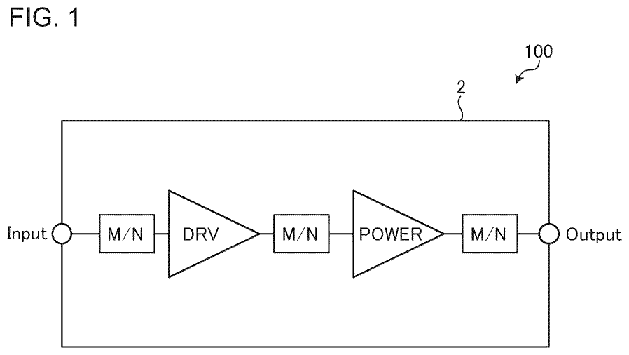

FIG. 1 is a schematic diagram showing an example of a power amplification module. A power amplification module 100 amplifies an inputted high-frequency input signal (Input) and outputs a high-frequency output signal (Output). FIG. 1 illustrates a configuration including a power amplifier (PA) having a configuration of two stages, which are a drive stage and a power stage. FIG. 1 illustrates a configuration in which an impedance matching circuit M/N is provided in a stage prior to a drive-stage power amplifier DRV, in a stage between the drive-stage power amplifier DRV and a power-stage power amplifier POWER, and in a stage subsequent to the power-stage power amplifier POWER.

In the present disclosure, the power amplification module 100 is not limited to a PA having a configuration of two stages, as shown in FIG. 1. The power amplification module 100 may be configured with a power amplifier of a single stage, for example, or may be configured with an amplifier having three or more stages connected in multiple stages.

In the present disclosure, the power amplification module 100 is an ultra-compact integrated module in which a plurality of integrated circuits and various functional components are mounted on a substrate 2 formed of, for example, a ceramic laminated substrate, such as a low-temperature co-fired ceramic (LTCC) substrate, a resin multilayer substrate, a film substrate, or the like.

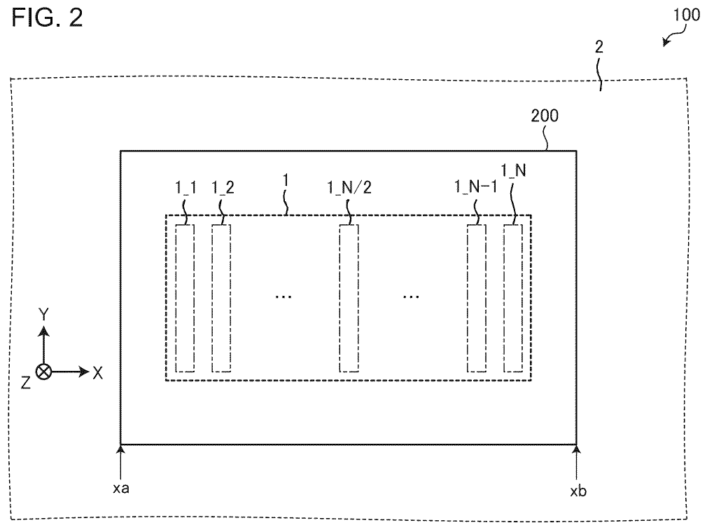

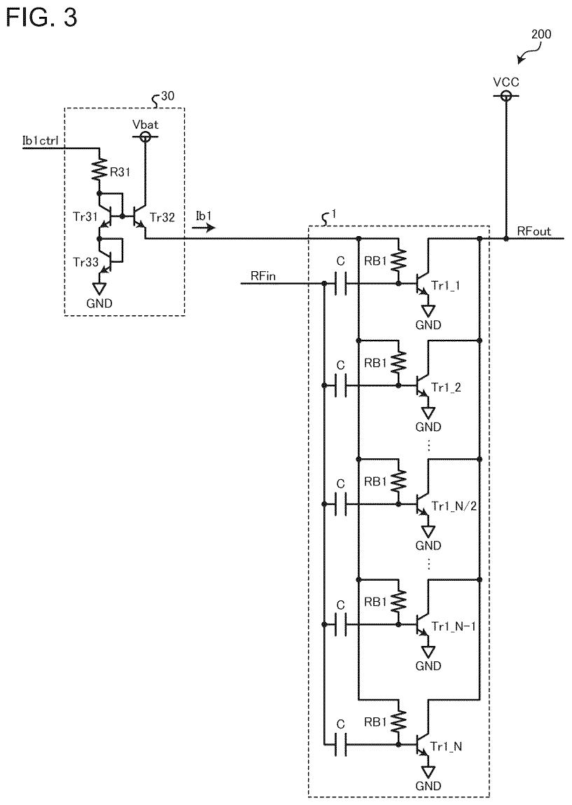

FIG. 2 is a transparent top view of a semiconductor device. FIG. 2 illustrates a semiconductor device 200 constituting the power-stage power amplifier POWER shown in FIG. 1. FIG. 3 is a diagram showing an example of an internal circuit configuration of the semiconductor device.

As the semiconductor device 200, an HBT device (integrated circuit) composed of, for example, GaAs (gallium arsenide) based heterojunction bipolar transistors (HBTs) is exemplified.

In the present disclosure, the semiconductor device 200 includes a semiconductor element 1 having N junctions 1_n (n is an integer from 2 to N) arranged in the X direction. Specifically, the semiconductor element 1 is a bipolar transistor having a so-called multi-finger structure in which N transistors Tr1_n are electrically connected in parallel. Here, the term “junction” refers to a junction in which a p-type semiconductor and an n-type semiconductor are pn-junctioned; and as an example, the junction between the base layer and the collector layer of the bipolar transistor is shown. Each junction 1_n shown in FIG. 2 corresponds to each transistor Tr1_n shown in FIG. 3.

The emitter of each transistor Tr1_n is electrically connected to a reference potential. The reference potential is exemplified by a ground potential GND; however, in the present disclosure, the reference potential is not limited the ground potential GND.

A high-frequency input signal RFin is inputted to the base of each transistor Tr1_n via a capacitor C. A current supplied from a bias circuit 30 via a resistor RB1 flows through the base of each transistor Tr1_n. The sum of the currents flowing through the base of each transistor Tr1_n is equal to a bias current Ib1 supplied from the bias circuit 30.

A power supply potential VCC is applied to the collector of each transistor Tr1_n. The high-frequency signal power-amplified by the semiconductor element 1 is outputted as a high-frequency output signal RFout.

In the configuration shown in FIG. 3, the resistance value of the resistor RB1 is set to, for example, 150 Ω. The capacitance value of the capacitor C is set to, for example, 0.8 pF. Further, in the configuration shown in FIG. 3, the resistance value of a resistor R31 of the bias circuit 30 is set to, for example, 100 Ω.

The bias circuit 30, to which a bias power supply potential Vbat is applied, supplies the bias current Ib1, which corresponds to a bias control current Ib1ctrl, to the semiconductor element 1. The bias control current Ib1ctrl is supplied from, for example, a control circuit (not shown) provided inside or outside the power amplification module 100.

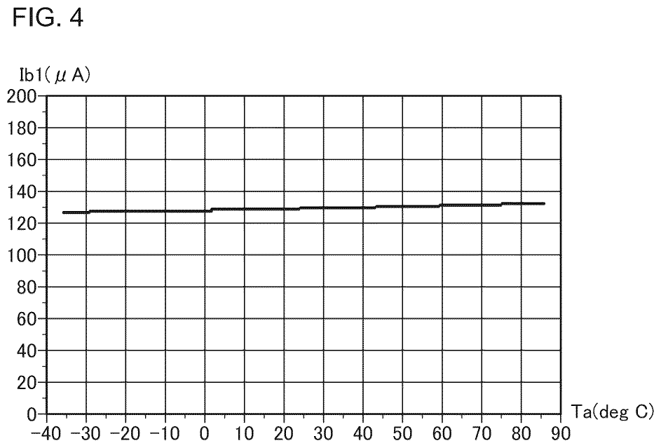

FIG. 4 is a schematic graph showing an example of temperature characteristics of the bias current supplied to the semiconductor element. As shown in FIG. 4, the bias current Ib1 supplied to the semiconductor element 1 has a substantially constant value (in the example shown in FIG. 4, the value is substantially 130 μA) regardless of the ambient temperature Ta. Here, it is assumed that each transistor Tr1_n has substantially the same characteristics. In such a case, the current flowing through the base of each transistor Tr1_n is substantially constant regardless of the ambient temperature Ta. At this time, the change in temperature of the junction 1_n of each transistor Tr1_n with respect to the change in ambient temperature Ta is substantially constant.

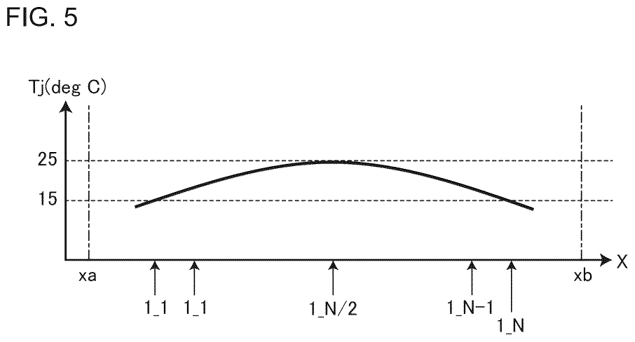

The bipolar transistors constituting the semiconductor device 200 generally have lower breakdown voltages under a low temperature environment. FIG. 5 is a schematic graph showing junction temperatures of the semiconductor device under a cryogenic environment. FIG. 5 illustrates the junction temperatures of the semiconductor device at an ambient temperature Ta of −30 degrees Centigrade. In FIG. 5, the horizontal axis represents the X direction shown in FIG. 2.

As shown in FIG. 5, the distribution of the junction temperatures in the semiconductor device 200 is biased. Specifically, the junction temperatures near the end portions of the semiconductor device 200 are relatively lower than the junction temperatures near the central portion of the semiconductor device 200, whose temperature tends to rise due to thermal interference between the transistors Tr1_n. FIG. 5 shows an example in which the junction temperatures Tj at the positions corresponding to the junctions 1_1 and 1_N of the transistors Tr1_1 and Tr1_N near the end portions of the semiconductor device 200 are 15 degrees Centigrade, and the junction temperature Tj at the position corresponding to the junction 1_N/2 of the transistor Tr1_N/2 near the central portion of the semiconductor device 200 is 25 degrees Centigrade

Due to non-uniformity of the heat dissipation of the semiconductor device 200, there is a possibility that overvoltage may occur at the junctions located in the end portions of the device under a low temperature environment, so that the required specification of the operating temperature range may be unmet. Hereinafter, a configuration of a semiconductor device and a power amplification device capable of expanding the lower limit of the operating temperature range will be described.

### Embodiment 1

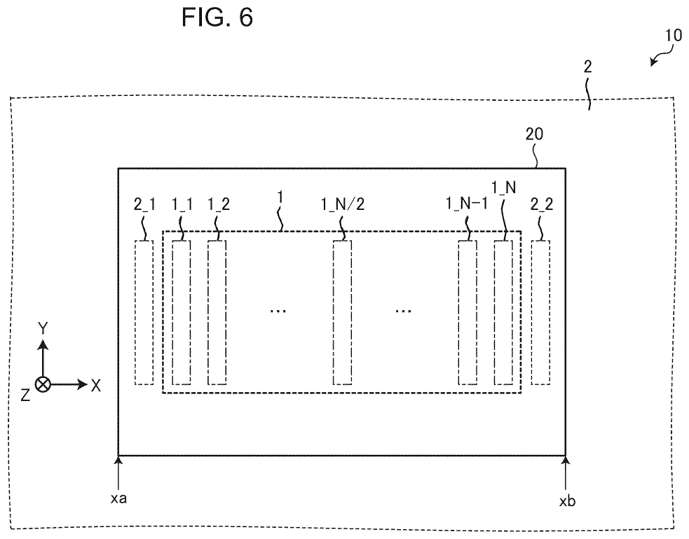

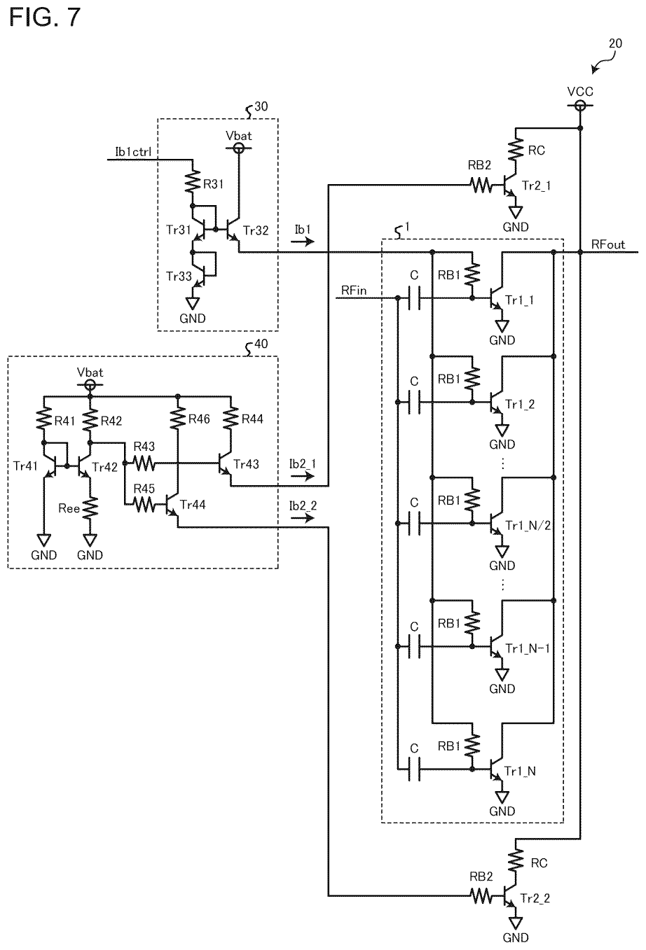

FIG. 6 is a transparent top view of a semiconductor device according to Embodiment 1. FIG. 6 illustrates a semiconductor device 20 constituting the power-stage power amplifier POWER shown in FIG. 1. As the semiconductor device 20, an HBT device having a configuration identical to that shown in FIG. 2 described above is exemplified. FIG. 7 is a diagram showing an example of an internal circuit configuration of the semiconductor device according to Embodiment 1.

In the semiconductor device 20 according to Embodiment 1, the configuration of a first semiconductor element 1 is substantially the same as that of the semiconductor element 1 described with reference to FIGS. 2 and 3.

The semiconductor device 20 according to Embodiment 1 includes, in addition to the first semiconductor element 1, a second semiconductor element provided with junctions 2_1 and 2_2 at both end portions in the arrangement direction of the junction 1_n (X direction). In Embodiment 1, the second semiconductor element is transistors Tr2_1 and Tr2_2. The junctions 2_1 and 2_2 shown in FIG. 6 correspond to the transistors Tr2_1 and Tr2_2 shown in FIG. 7, respectively.

The emitters of the transistors Tr2_1 and Tr2_2 are electrically connected to the reference potential. Bias currents Ib2_1 and Ib2_2 supplied from a bias circuit 40 via a resistor RB2 flow through the base of each of the transistors Tr2_1 and Tr2_2. A power supply potential VCC is supplied to the collectors of the transistors Tr2_1 and Tr2_2 via resistors RC. That is, the resistors RC are provided between the collector of each transistor Tr1_n, which is the power feeding point of the power supply potential VCC to the first semiconductor element 1, and the collectors of the transistors Tr2_1 and Tr2_2, which are the power feeding points of the power supply potential VCC to the second semiconductor element.

In the configuration shown in FIG. 7, the resistance value of the resistor RB2 of the second semiconductor element (transistors Tr2_1 and Tr2_2) is set to, for example, 100 Ω. The resistance value of the resistor RC is set to, for example, 1000 Ω. Thus, isolation between each transistor Tr1_n of the first semiconductor element 1 and the transistors Tr2_1 and Tr2_2 is ensured.

In the configuration shown in FIG. 7, the resistance value of a resistor R41 of the bias circuit 40 is set to, for example, 350 Ω. The resistance value of a resistor R42 is set to, for example, 4500 Ω. The resistance value of each of the resistors R43, R44, R45 and R46 is set to, for example, 1000 Ω. The resistance value of a resistor Ree is set to, for example, substantially 400 Ω.

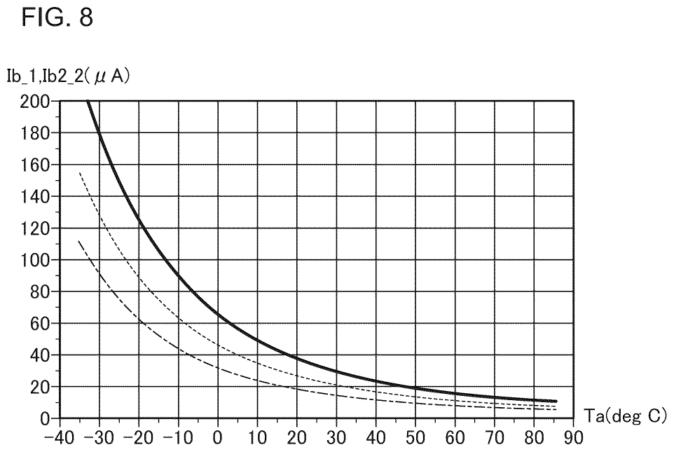

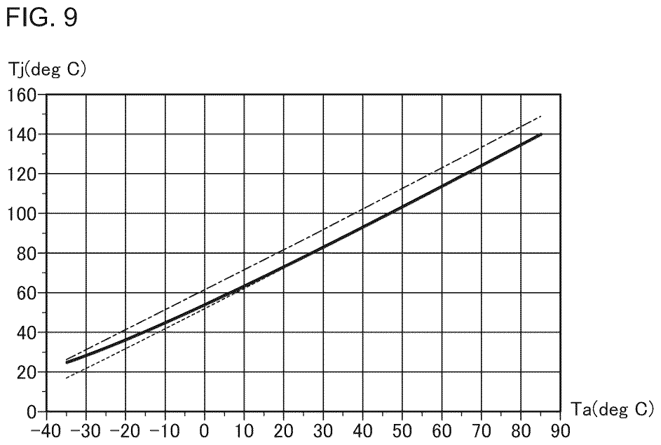

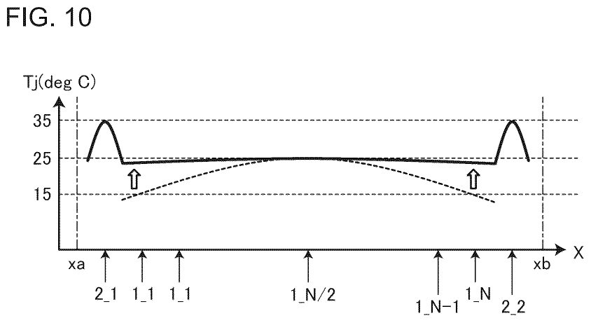

FIG. 8 is a schematic graph showing an example of temperature characteristics of the bias currents supplied to the second semiconductor element. FIG. 9 is a diagram showing an example of the change in junction temperature of the semiconductor device according to Embodiment 1 with respect to the change in ambient temperature. FIG. 10 is a schematic graph showing the junction temperature of the semiconductor device according to Embodiment 1 under a cryogenic environment.

In FIG. 8, a solid line shows an example of temperature characteristics when the resistance value of the resistor Ree is 405 Ω, a broken line shows an example of temperature characteristics when the resistance value of the resistor Ree is 400 Ω, and a dashed line shows an example of temperature characteristics when the resistance value of the resistor Ree is 395 Ω.

In FIG. 9, a solid line shows the change in junction temperature at the positions corresponding to the junctions 1_1 and 1_N near the end portions of the semiconductor device 20. Further, in FIG. 9, a broken line shows the change in junction temperature at the positions corresponding to the junctions 1_1 and 1_N near the end portions of the semiconductor device 200 having the configuration shown in FIGS. 2 and 3. Further, in FIG. 9, a dashed line shows the change in junction temperature at the position corresponding to the junction 1_N/2 near the central portion of the semiconductor device 20 having the configuration according to Embodiment 1.

In FIG. 10, the junction temperatures of the semiconductor device 20 at an ambient temperature Ta of −30 degrees Centigrade are illustrated. In FIG. 10, the horizontal axis represents the X direction shown in FIG. 6.

As shown in FIG. 4, the bias current Ib1 supplied to the first semiconductor element 1 has a substantially constant value regardless of the ambient temperature Ta. In other words, the current flowing through the base of each transistor Tr1_n of the first semiconductor element 1 is substantially constant regardless of the ambient temperature Ta. As a result, the current flowing through each transistor Tr1_n of the first semiconductor element 1 is substantially constant regardless of the ambient temperature Ta. Therefore, the change in heating value of the first semiconductor element 1 caused by the change in ambient temperature Ta is within an extremely small range.

In contrast, as shown in FIG. 8, due to the temperature characteristics of the on-voltage in the active region of a transistor Tr42, the lower the ambient temperature Ta is, the more the bias currents Ib2_1 and Ib2_2 supplied to the second semiconductor element (transistors Tr2_1 and Tr2_2) increase. More specifically, the lower the ambient temperature Ta is, the more the on-voltage in the active region of the transistor Tr42 becomes larger, and when the base-emitter voltage of the transistors Tr2_1 and Tr2_2 and transistors Tr43 and Tr44 Darlington-connected to the transistors Tr2_1 and Tr2_2 exceeds the on-voltage, the bias currents Ib2_1 and Ib2_2 rapidly increase. Accordingly, the lower the ambient temperature Ta is, the greater the currents flowing through the transistors Tr2_1 and Tr2_2 relatively increases. As a result, the lower the ambient temperature Ta is, the more the heating value of the transistors Tr2_1 and Tr2_2 increases, and therefore the more the junction temperature at the positions corresponding to the junctions 2_1 and 2_2 of the second semiconductor element rises. As the junction temperature at the positions corresponding to the junctions 2_1 and 2_2 of the second semiconductor element rises, the closer to the junctions 2_1 and 2_2 of the second semiconductor element, the more the junction temperature at the position corresponding to each junction 1_n of the first semiconductor element 1 rises.

In the configuration shown in FIG. 7, by appropriately setting the resistance values of the resistor RB2 and the resistor RC of the second semiconductor element, and the resistance values of the resistor R41, the resistor R42, each of the resistors R43, R44, R45 and R46, and the resistor Ree of the bias circuit 40, it is possible to, for example, set the junction temperature of the junctions 1_1 and 1_N of the transistors Tr1_1 and Tr1_N near the end portions of the semiconductor device 20 to match the junction temperature of the junction 1_N/2 of the transistor Tr1_N/2 near the central portion of the semiconductor device 20 under a cryogenic environment (for example, −30 degrees Centigrade), as shown in FIG. 9. Thus, for example, as shown in FIG. 10, the junction temperature at the position corresponding to each junction 1_n of the first semiconductor element 1 can be made substantially uniform under a cryogenic environment (for example, −30 degrees Centigrade).

### Embodiment 2

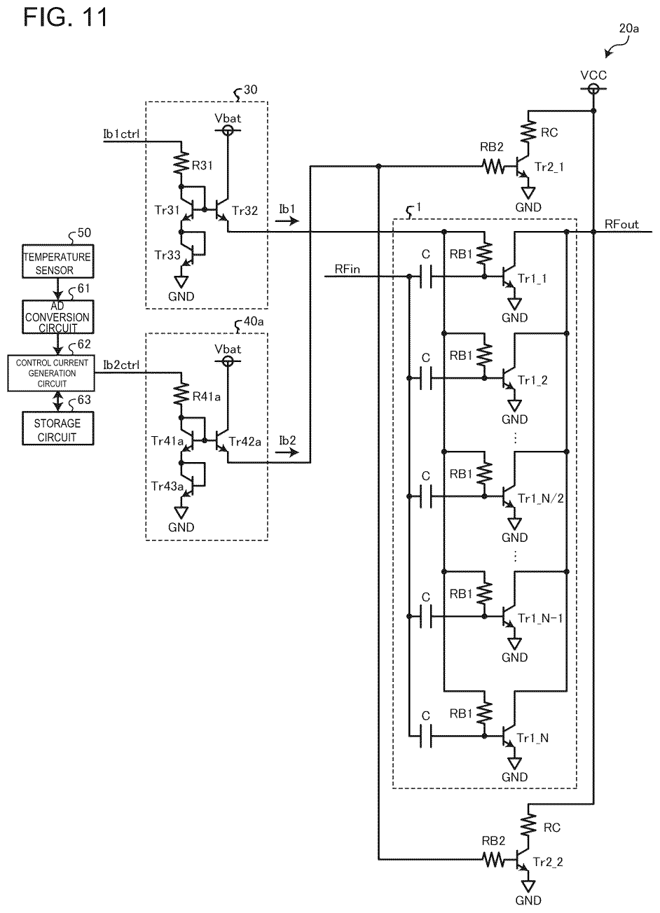

FIG. 11 is a diagram showing an example of an internal circuit configuration of a semiconductor device according to Embodiment 2. In a semiconductor device 20a according to Embodiment 2, the configurations of a first semiconductor element 1 and a second semiconductor element (transistors Tr2_1 and Tr2_2) is substantially the same as that of the semiconductor device 20 described in Embodiment 1.

Embodiment 2 describes a configuration that includes: a temperature sensor (thermistor) 50 that detects an ambient temperature; an AD conversion circuit 61 that converts the value detected by the temperature sensor 50 to digital; a control current generation circuit 62 that generates a bias control current Ib2ctrl supplied to a bias circuit 40a; and a storage circuit 63 that stores, as a current control table, the relationship between the temperature detected by the temperature sensor 50 and the bias control current Ib2ctrl.

The control current generation circuit 62 refers to the current control table stored in the storage circuit 63 to generate the bias control current Ib2ctrl, which corresponds to the value detected by the temperature sensor 50. The bias circuit 40a supplies a bias current Ib2, which corresponds to the bias control current Ib2ctrl, to the second semiconductor element (transistors Tr2_1 and Tr2_2). Thus, it is easy to change the temperature setting.

### Embodiment 3

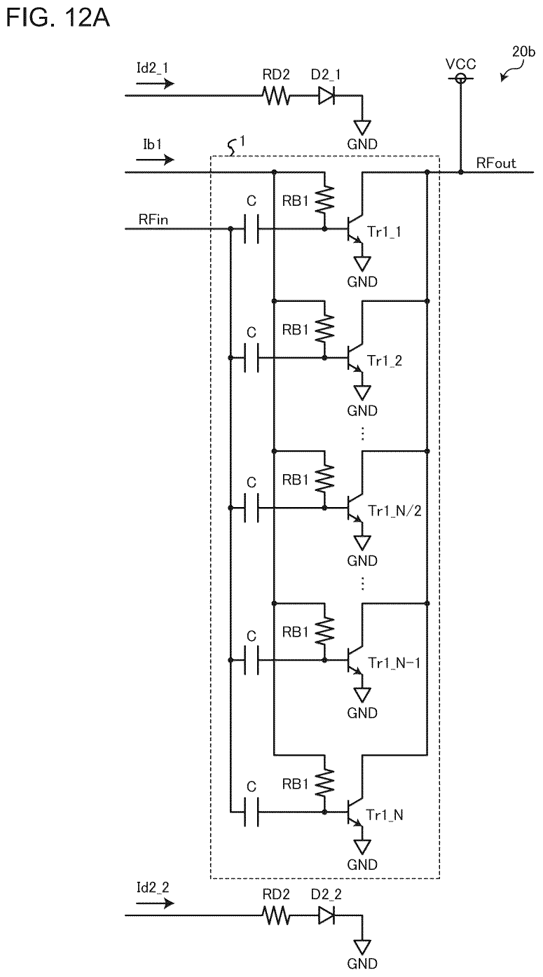

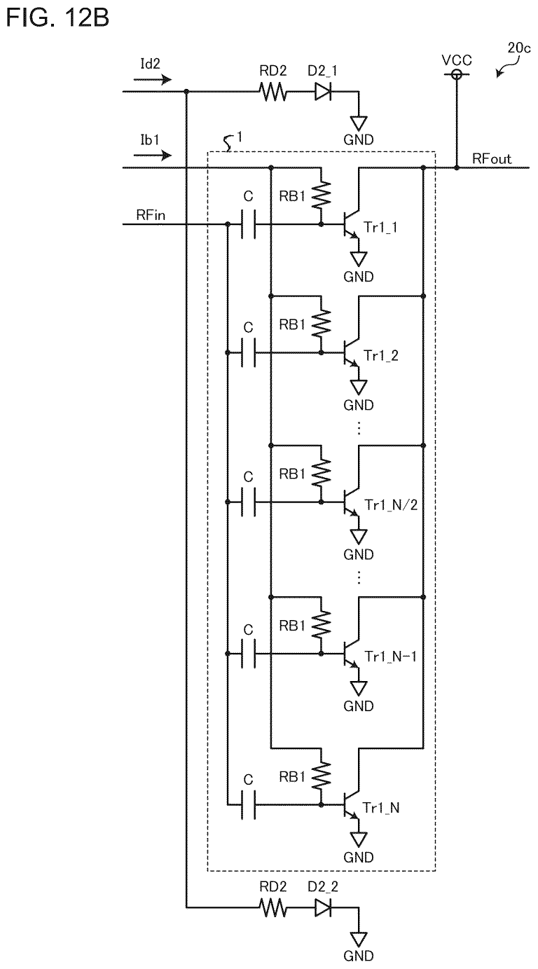

FIGS. 12A and 12B are diagrams showing an example of an internal circuit configuration of a semiconductor device according to Embodiment 3. In semiconductor devices 20b and 20c according to Embodiment 3, the configuration of a first semiconductor element 1 is substantially the same as that of the semiconductor device 20 described in Embodiment 1.

In Embodiment 3, a second semiconductor element is diodes D2_1 and D2_2. The junctions of the diodes D2_1 and D2_2 correspond to the junctions 2_1 and 2_2 shown in FIG. 6, respectively. In the configuration shown in FIG. 12A, the resistance value of resistors RD2 of the second semiconductor element (diodes D2_1 and D2_2) is set to, for example, 100 Ω. FIG. 12A illustrates a configuration in which forward currents Id2_1 and Id2_2 are supplied to the diodes D2_1 and D2_2, respectively. FIG. 12B illustrates a configuration in which a current Id2, which is the sum of the forward currents of the diodes D2_1 and D2_2, is supplied.

In each configuration of Embodiment 3 shown in FIGS. 12A and 12B, by applying the bias circuit 40 of Embodiment 1 and appropriately setting each resistance value, it is possible to, for example, set the junction temperature of the junctions 1_1 and 1_N of the transistors Tr1_1 and Tr1_N near the end portions of the semiconductor device 20b to match the junction temperature of the junction 1_N/2 of the transistor Tr1_N/2 near the central portion of the semiconductor device 20b under a cryogenic environment.

Alternatively, in each configuration of Embodiment 3 shown in FIGS. 12A and 12B, by applying the temperature sensor 50, the AD conversion circuit 61, the control current generation circuit 62, the storage circuit 63, and the bias circuit 40a of Embodiment 2, temperature setting can be easily changed.

### Embodiment 4

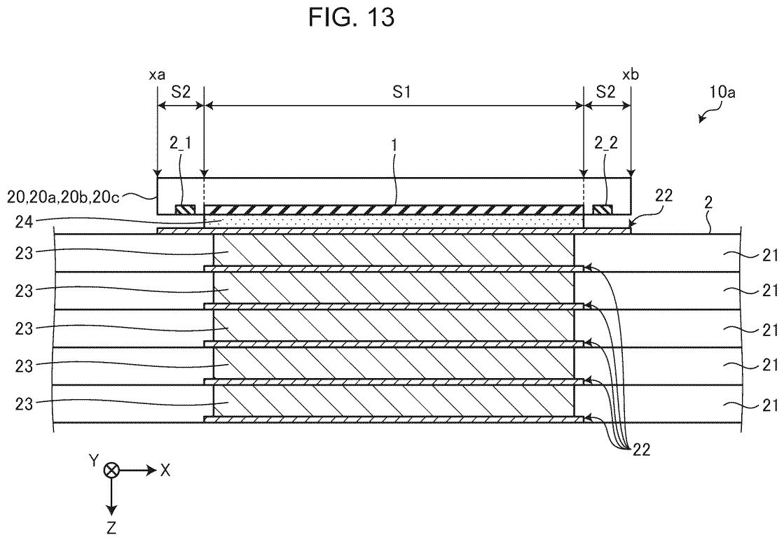

FIG. 13 is a cross-sectional view taken along the X direction of a power amplification module according to Embodiment 4. In Embodiment 4, the internal circuit configurations of the semiconductor devices 20, 20a, 20b, and 20c correspond to the configurations of Embodiments 1, 2, and 3 described above, respectively. In Embodiment 4, the semiconductor device 20, 20a, 20b, or 20c is flip-chip mounted on a substrate 2 of a power amplification module 10a.

The substrate 2 is provided with a plurality of reference potential surfaces 22 (GND layers) with a plurality of dielectric layers 21 interposed therebetween, and the reference potential surfaces 22 are connected to each other by through-vias 23 to form a heat dissipation structure. In the power amplification module 10a according to Embodiment 4 shown in FIG. 13, a stripe bump 24 long in the X direction is provided between a reference potential surface of the semiconductor device 20, 20a, 20b, or 20c (GND layer provided on the chip surface) and the reference potential surface 22 provided on a component mounting surface of the substrate 2.

As shown in FIG. 13, in the power amplification module 10a according to Embodiment 4, when the substrate 2 is viewed in a plan view in the Z direction, the stripe bump 24 is provided in a region S1 overlapping each junction 1_n of the first semiconductor element 1 and is not provided in a region S2 overlapping the junctions 2_1 and 2_2 of the second semiconductor element. Thus, the heat dissipation from the positions corresponding to the junctions 2_1 and 2_2 of the second semiconductor element is suppressed. Thus, the junction temperature at the positions corresponding to the junctions 2_1 and 2_2 of the second semiconductor element can be increased.

### Embodiment 5

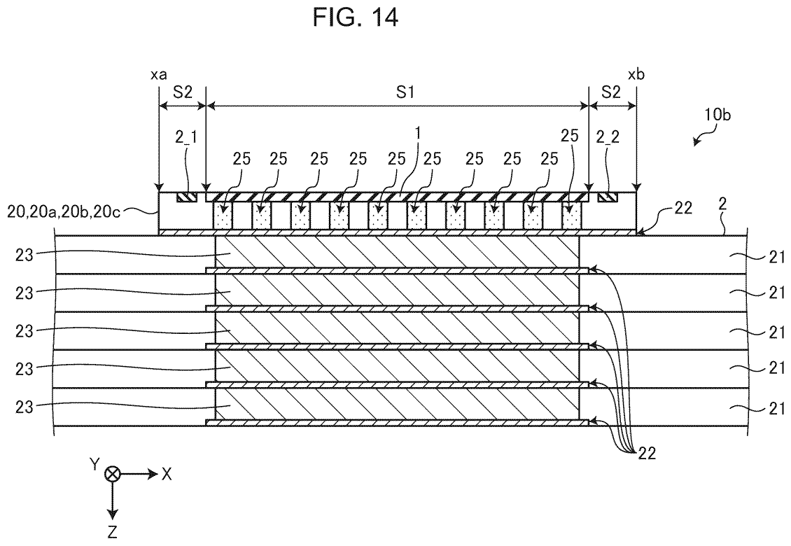

FIG. 14 is a cross-sectional view taken along the X direction of a power amplification module according to Embodiment 5. In Embodiment 5, the internal circuit configurations of the semiconductor devices 20, 20a, 20b, and 20c correspond to the configurations of Embodiments 1, 2, and 3 described above, respectively. In Embodiment 5, the semiconductor device 20, 20a, 20b, or 20c is wire-bonded to a substrate 2 of a power amplification module 10b.

The configuration of the substrate 2 is the same as that of Embodiment 4. As shown in FIG. 14, in the semiconductor device 20, 20a, 20b, or 20c of the power amplification module 10b according to Embodiment 5, when the substrate 2 is viewed in a plan view in the Z direction, heat dissipating vias 25 are provided in a region S1 overlapping each junction 1_n of the first semiconductor element 1, and the heat dissipating vias 25 are not provided in a region S2 overlapping the junctions 2_1 and 2_2 of the second semiconductor element. The heat dissipating vias 25 refer to vias passing through the semiconductor device 20, 20a, 20b, or 20c. Thus, the heat dissipation from the positions corresponding to the junctions 2_1 and 2_2 of the second semiconductor element is suppressed. Thus, the junction temperature at the positions corresponding to the junctions 2_1 and 2_2 of the second semiconductor element can be increased.

In the embodiments described above, the transistor constituting the semiconductor device 200 is exemplified by a bipolar transistor; however, the transistor constituting the semiconductor device 200 is not limited to being a bipolar transistor, but may be, for example, a MOSFET. In such a case as well, due to non-uniformity of heat dissipation of the semiconductor device, there is a possibility that, under a low temperature environment, overvoltage may occur in the channel portions of the MOSFET located in the end portions of the device, so that the required specification of the operating temperature range may be unmet.

The embodiments described above are intended to facilitate understanding of the present disclosure, and are not intended to limit the interpretation thereof. The present disclosure may be changed/modified without necessarily departing from its scope, and the present disclosure also includes equivalents thereof.

The present disclosure may have the following configurations as described above or in lieu of the above.

(1) A semiconductor device according to an aspect of the present disclosure includes: a first semiconductor element in which a plurality of transistors arranged in one direction are electrically connected in parallel; and a second semiconductor element provided in both end portions in the arrangement direction of the transistors, wherein the lower an ambient temperature is, the greater a current flowing through the second semiconductor element relatively increases.

In such a configuration, the lower the ambient temperature is, the more the heating value of the second semiconductor element increases, and therefore the more the junction temperature at the position corresponding to the junction of the second semiconductor element rises. Accordingly, the closer to the junction of the second semiconductor element, the more the junction temperature rises at the position corresponding to each junction of the first semiconductor element.

(2) In the semiconductor device according to (1), the second semiconductor element is a transistor.

In such a configuration, the lower the ambient temperature is, the more the heating value of the transistor increases, and therefore the more the junction temperature at the position corresponding to the junction of second semiconductor element rises. Accordingly, the closer to the junction of the transistor, the more the junction temperature rises at the position corresponding to each junction of the first semiconductor element.

(3) In the semiconductor device according to (2), a resistor is provided between a power feeding point to the first semiconductor element and a power feeding point to the second semiconductor element.

In such a configuration, isolation between the first semiconductor element and the second semiconductor element is ensured.

(4) In the semiconductor device according to (1), the second semiconductor element is a diode.

In such a configuration, the lower the ambient temperature is, the more the heating value of the diode increases, and therefore the more the junction temperature at the position corresponding to the junction of the diode rises. Accordingly, the closer to the junction of the diode, the more the junction temperature rises at the position corresponding to each junction of the first semiconductor element.

(5) A power amplification module according to an aspect of the present disclosure includes: the semiconductor device described above; a substrate on which the semiconductor device is flip-chip mounted; and a bump provided between the semiconductor device and the substrate, wherein, in plan view, the bump is provided in a region overlapping the first semiconductor element and is not provided in a region overlapping the second semiconductor element.

In such a configuration, the heat dissipation from the position corresponding to the junction of the second semiconductor element is suppressed. As a result, the junction temperature at the position corresponding to the junction of the second semiconductor element can be increased.

(6) A power amplification module according to an aspect of the present disclosure includes: the semiconductor device described above; and a substrate on which the semiconductor device is wire-bonded, wherein, in plan view, the semiconductor device is provided with a heat dissipating via in a region overlapping the first semiconductor element and is not provided with the heat dissipating via in a region overlapping the second semiconductor element.

In such a configuration, the heat dissipation from the position corresponding to the junction of the second semiconductor element is suppressed. As a result, the junction temperature at the position corresponding to the junction of the second semiconductor element can be increased.

According to the present disclosure, it is possible to realize a semiconductor device and a power amplification module capable of expanding the lower limit of the operating temperature range.

What is claimed is:

1. A semiconductor device comprising:
a first semiconductor element comprising a plurality of transistors physically arranged in a first direction and electrically connected in parallel with each other; and
a second semiconductor element at one or both ends of the first semiconductor element in the first direction,
wherein a level of a current flowing through the second semiconductor is related to an ambient temperature, such that as the ambient temperature decreases, the level of the current flowing through the second semiconductor element relatively increases.

2. The semiconductor device according to claim 1, wherein the second semiconductor element comprises a transistor.

3. The semiconductor device according to claim 2, further comprising:
a resistor between a power feeding point of the first semiconductor element and a power feeding point of the second semiconductor element.

4. The semiconductor device according to claim 1, wherein the second semiconductor element comprises a diode.

5. A power amplification module comprising:
the semiconductor device according to claim 1;
a substrate on which the semiconductor device is flip-chip mounted; and
a bump between the semiconductor device and the substrate,
wherein, in a plan view of the substrate, the bump is in a region overlapping the first semiconductor element, and is not in a region overlapping the second semiconductor element.

6. A power amplification module comprising:
the semiconductor device according to claim 1; and
a substrate on which the semiconductor device is wire-bonded,
wherein, in a plan view of the substrate, the semiconductor device comprises a heat dissipating via in a region overlapping the first semiconductor element, and not in a region overlapping the second semiconductor element.
